(19) United States
(12) Patent Application Publication
(10) Pub. No.: US 2007/0090426 A1
(43) Pub. Date: Apr. 26, 2007

(54) Ferroelectric capacitor

(76) Inventor: Kazunori Isogai, Kyoto (JP)

Correspondence Address: MCDERMOTT WILL & EMERY LLP, 600 13TH STREET, NW, WASHINGTON, DC, 20005-3096, US

(21) Appl. No.: 11/493,525

(22) Filed: Jul. 27, 2006

(30) Foreign Application Priority Data
Oct. 20, 2005 (JP) 2005-305994

(51) Int. Cl. H01L 29/94; H01L 29/76; H01L 31/00; H01L 29/00; H01L 27/108; H01L 31/119

(52) U.S. Cl. 257/295; 257/46; 257/310

(57) ABSTRACT

A ferroelectric capacitor includes a bottom electrode formed on a substrate, a ferroelectric material film formed on the bottom electrode and a top electrode formed on the ferroelectric material film. The ferroelectric material film is predominantly made of a compound represented by the general formula of SrₓBi_{y}Ta_{2-z}Nb_{z}O₉ (wherein 0.69≦x≦0.81, 2.09≦y≦2.31 and z=0 or 0.35≦z≦0.98).

### CROSS-REFERENCE TO RELATED APPLICATION

This non-provisional application claims priority under 35 U.S.C. §119(a) of Japanese Patent Application No. 2005-305994 filed in Japan on Oct. 20, 2005, the entire contents of which are hereby incorporated by reference.

### BACKGROUND OF THE INVENTION

1. Field of the Invention

The present invention relates to a ferroelectric capacitor. In particular, it relates to a ferroelectric capacitor using a ferroelectric material film made of strontium bismuth tantalum oxide material as a capacitance insulating film.

2. Description of Related Art

Charge content of a ferroelectric capacitor is determined by multiplying remnant polarization density (2Pr) by an area in which polarization occurs (polarization area). As the design rules of semiconductor devices become finer, the polarization area is reduced to make it impossible for conventional flat capacitors to retain the required charge content. For this reason, the structure of the capacitors has been modified three-dimensionally or the purpose of ensuring a sufficient polarization area and considerably reducing space occupied by the capacitor.

For realization of the three-dimensionally modified capacitors, it is essential to form a ferroelectric material film having high 2Pr and uniform thickness along the three-dimensionally modified configuration. However, it is difficult to provide the ferroelectric material film of uniform thickness along such configuration by spin coating or sputtering commonly used for forming the ferroelectric material film. Therefore, attention has been focused on metal-organic chemical vapor deposition (MOCVD) as a new method for forming the ferroelectric material film.

The 2Pr of the ferroelectric material film varies depending on the composition, production method and thickness of the ferroelectric material film. In order to obtain a ferroelectric material film with high 2Pr by MOCVD, the composition of the ferroelectric material film has to be optimized. Domestic Re-Publication of PCT International Publication WO2002/058129 discloses a method for forming a high 2Pr strontium bismuth tantalum oxide (SrₓBi_{y}Ta₂O₉, hereinafter referred to as SBT) film by MOCVD. This method allows production of a ferroelectric material film containing strontium x and bismuth y in the ratios of 0.90≦x<1.00 and 1.70<y≦3.20, respectively, such that 2Pr as high as about 16 μC/cm² is exhibited when a voltage of 2V is applied.

### SUMMARY OF THE INVENTION

In the conventional method for forming the ferroelectric material film by MOCVD, however, there is a problem in that the thickness of the obtained high 2Pr ferroelectric material film is limited to about 300 nm.

The ferroelectric capacitors are required to perform high speed data writing at low voltage as the semiconductor devices are shifted to finer design rules. The writing speed is in proportion to the intensity of an electric field applied to the ferroelectric material film. The applied electric field is in proportion to the applied voltage and in inverse proportion to the thickness of the ferroelectric material film. Therefore, in order to perform high speed data writing at low voltage, it is essential to reduce the thickness of the ferroelectric material film. Further, space occupied by the capacitor is substantially determined by the sum of the thicknesses of the top electrode, ferroelectric film and bottom electrode. Therefore, from the viewpoint of reduction of the occupied space, the ferroelectric material film has to be thinned down. Specifically, the thickness of the SBT film is required to be reduced to 100 nm or less.

The inventor of the present invention actually formed SBT films of 100 nm or less in thickness. However, with the compositions described in Domestic Re-Publication of PCT International Publication WO2002/058129, the highest 2Pr value obtained was about 10 μC/cm².

As a solution to the conventional problem, the present invention provides a ferroelectric capacitor including a strontium bismuth tantalum oxide film having a high remnant polarization density even if it is 100 nm or less in thickness.

In order to achieve the object, the present invention provides a ferroelectric capacitor including a ferroelectric material film having the general formula of SrₓBi_{y}Ta₂O₉ (wherein 0.69≦x≦0.81 and 2.09≦y≦2.31).

More specifically, the ferroelectric capacitor of the present invention includes: a bottom electrode formed on a substrate; a ferroelectric material film formed on the bottom electrode and predominantly made of a compound represented by the general formula of SrₓBi_{y}Ta_{2-z}Nb_{z}O₉ (wherein 0.69≦x≦0.81, 2.09≦y≦2.31 and z=0 or 0.35≦z≦0.98); and a top electrode formed on the ferroelectric material film.

As to the ferroelectric capacitor, the ferroelectric material film is likely to take a layered perovskite crystal structure even if it is thin. Accordingly, the ferroelectric capacitor is operated at low voltage and high speed. If Nb is contained in the ferroelectric material film, the remnant polarization density in the ferroelectric material film is less varied, thereby improving the yield of the ferroelectric capacitor.

As to the ferroelectric capacitor of the present invention, the bottom electrode is formed on the substrate with a first interlayer insulating film interposed therebetween. With this configuration, the ferroelectric capacitor is used with ease as a capacitative element in a memory device.

As to the ferroelectric capacitor of the present invention, the sum of the Sr ratio and the Bi ratio is preferably 3.00±0.07. If the sum of the Sr ratio and the Bi ratio becomes substantially equal to 3 which is the stoichiometric ratio, the ferroelectric material film is provided with a favorable layered perovskite crystal structure with reliability.

As to the ferroelectric capacitor of the present invention, the thickness of the ferroelectric material film is preferably larger than 0 nm and not larger than 100 nm. Even with the thus determined thickness, the remnant polarization density of 14.2 to 17.4 μC/cm² is achieved.

As to the ferroelectric capacitor of the present invention, the ferroelectric material film is preferably formed by metal-organic chemical vapor deposition. According to this method, the ferroelectric material film is provided with uniform thickness along the three-dimensionally modified structure with the remnant polarization density kept high. Thus, the capacitor is provided under finer design rules.

As to the ferroelectric capacitor of the present invention, it is preferred that a second interlayer insulating film having a recess is formed on the substrate, the ferroelectric material film is formed along the shape of the recess and the ratio between the maximum thickness and the minimum thickness of the ferroelectric material film formed along the shape of the recess is 0.8 or higher. According to this structure, the ferroelectric capacitor is modified three-dimensionally and space for the ferroelectric capacitor is reduced. Further, the thickness of the ferroelectric material film is less varied and the electric field is applied to the ferroelectric material film with uniform intensity. Therefore, the ferroelectric capacitor is operated at high speed.

In this case, it is preferred that the second interlayer insulating film is formed on the substrate with the first interlayer insulating film interposed therebetween.

As to the ferroelectric capacitor of the present invention, it is preferred that the bottom electrode is formed to be projected from the surface of the substrate, the ferroelectric material film is formed along the shape of the bottom electrode and the ratio between the maximum thickness and the minimum thickness of the ferroelectric material film formed along the shape of the bottom electrode is 0.8 or higher. According to this structure, the ferroelectric capacitor is modified three-dimensionally and space for the ferroelectric capacitor is reduced. Further, the thickness of the ferroelectric material film is less varied and the ferroelectric capacitor is operated at high speed.

In this case, it is preferred that the bottom electrode is formed on the substrate with the first interlayer insulating film interposed therebetween.

As to the ferroelectric capacitor of the present invention, the bottom electrode is preferably made of a single metal oxide film or a stack of films including a metal oxide film arranged nearest the ferroelectric material film. Since a metal oxide electrode shows significant lattice mismatch with a SBT layered perovskite crystal structure as compared with a metal electrode. Accordingly, when the SBT film is thermally treated for crystallization, the lattice mismatch inhibits crystal growth along the c-axis where the remnant polarization density is zero. This makes it possible to improve the remnant polarization density a further extent.

As to the ferroelectric capacitor of the present invention, the ferroelectric material film preferably contains a rare earth element. The addition of the rare earth element makes it possible to improve the remnant polarization density to a further extent.

### BRIEF DESCRIPTION OF THE DRAWINGS

FIG. 1 is a sectional view illustrating a ferroelectric capacitor of a first embodiment of the present invention.

FIG. 2 is a graph illustrating the composition of a ferroelectric material film used in the ferroelectric capacitor of the first embodiment of the present invention.

FIG. 3 is a graph illustrating a relationship between composition and remnant polarization density in the ferroelectric material film used in the ferroelectric capacitor of the first embodiment of the present invention.

FIG. 4 is a graph illustrating a P—V hysteresis curve of the ferroelectric material film used in the ferroelectric capacitor of the first embodiment of the present invention.

FIG. 5 is a graph illustrating a relationship between Nb ratio and remnant polarization density in the ferroelectric material film used in the ferroelectric capacitor of the first embodiment of the present invention.

FIG. 6 is a graph illustrating a relationship between Nb ratio and variations in remnant polarization density in the ferroelectric material film used in the ferroelectric capacitor of the first embodiment of the present invention.

FIG. 7 is a graph illustrating a relationship between coercive voltage and Nb ratio in the ferroelectric material film used in the ferroelectric capacitor of the first embodiment of the present invention.

FIG. 8 is a sectional view illustrating a ferroelectric capacitor of a second embodiment of the present invention.

FIG. 9 is an electron micrograph illustrating the cross section of the ferroelectric capacitor of the second embodiment of the present invention before the formation of a top electrode.

FIG. 10 is a sectional view illustrating a ferroelectric capacitor according to a modification of the second embodiment of the present invention.

### DETAILED DESCRIPTION OF THE INVENTION

### First Embodiment

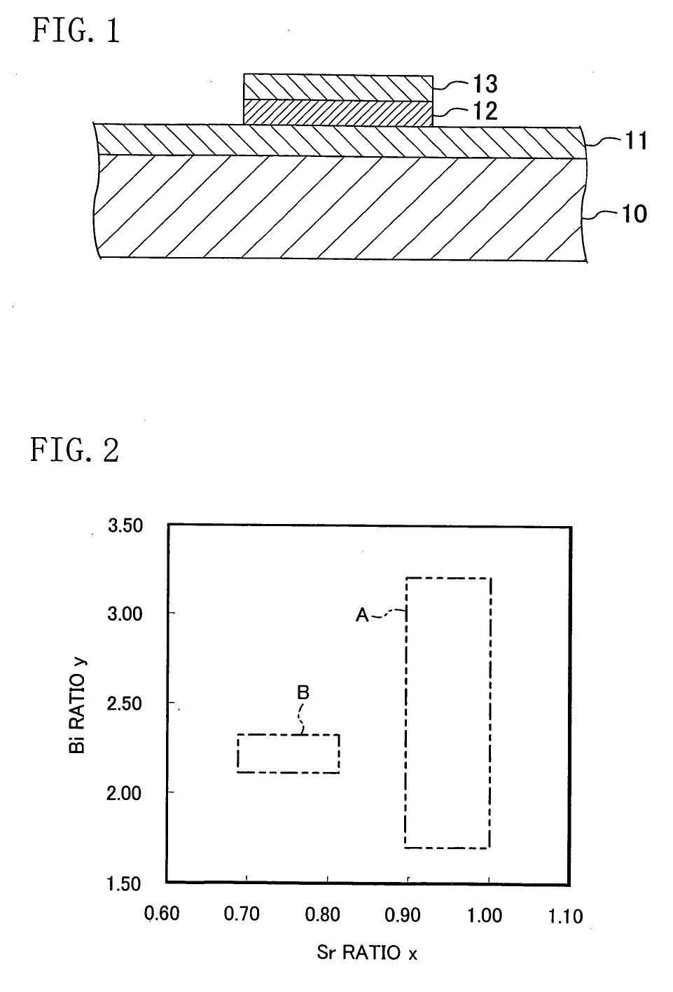

Explanation of a first embodiment of the present invention will be provided with reference to the drawings. FIG. 1 shows the sectional structure of a ferroelectric capacitor according to the first embodiment. As shown in FIG. 1, the ferroelectric capacitor of the first embodiment is a substantially flat capacitor including a bottom electrode 11 made of a 50 nm thick iridium oxide film formed on a substrate 10, a 60 nm thick strontium bismuth tantalum oxide (SBT) film 12 formed on the bottom electrode 11 as a ferroelectric material film and a top electrode 13 made of a 100 nm thick iridium oxide film formed on the SBT film 12.

The ferroelectric capacitor of the present embodiment is manufactured by the following method. First, a 200 nm thick silicon oxide film (not shown) is formed on a silicon substrate 10 by plasma CVD. A bottom electrode 11 made of a 50 nm thick iridium oxide film is formed on the silicon oxide film by sputtering. Then, a 60 nm thick SBT film 12 is deposited on the bottom electrode 11 by MOCVD at a substrate temperature of 400° C. or lower. The deposited SBT film 12 is amorphous in this stage. Then, a top electrode 13 made of a 100 nm thick iridium oxide film is formed on the SBT film 12 by sputtering. A 50 μm square resist pattern is formed on the top electrode 13 and the top electrode 13 and the SBT film 12 are etched using the resist pattern as a mask. Then, the resist is removed and thermal treatment is performed in an oxygen atmosphere at 800° C. for 1 minute to crystallize the SBT film 12.

The composition of the SBT film 12 may be varied by adjusting the feed rates of the organic metal materials Sr, Bi and Ta to the substrate. The composition of the SBT film is evaluated using an X-ray fluorescence analyzer (SMAT 2250 manufactured by TECNOS Co., Ltd.).

With the ferroelectric capacitor of the present embodiment, a study was made on a relationship between remnant polarization density (2Pr) value and SBT film composition. FIG. 2 is a graph illustrating a composition region A representing the composition of a conventional ferroelectric material film and a composition region B representing the composition of the ferroelectric material film of the present embodiment. In FIG. 2, the horizontal axis indicates the Sr ratio x normalized regarding the Ta ratio as 2 and the vertical axis indicates the Bi ratio y. The composition region A covers the range of 0.90≦x<1.00 and 1.70<y≦3.20, while the composition region B covers the range of 0.69≦x≦0.81 and 2.09≦y≦2.31.

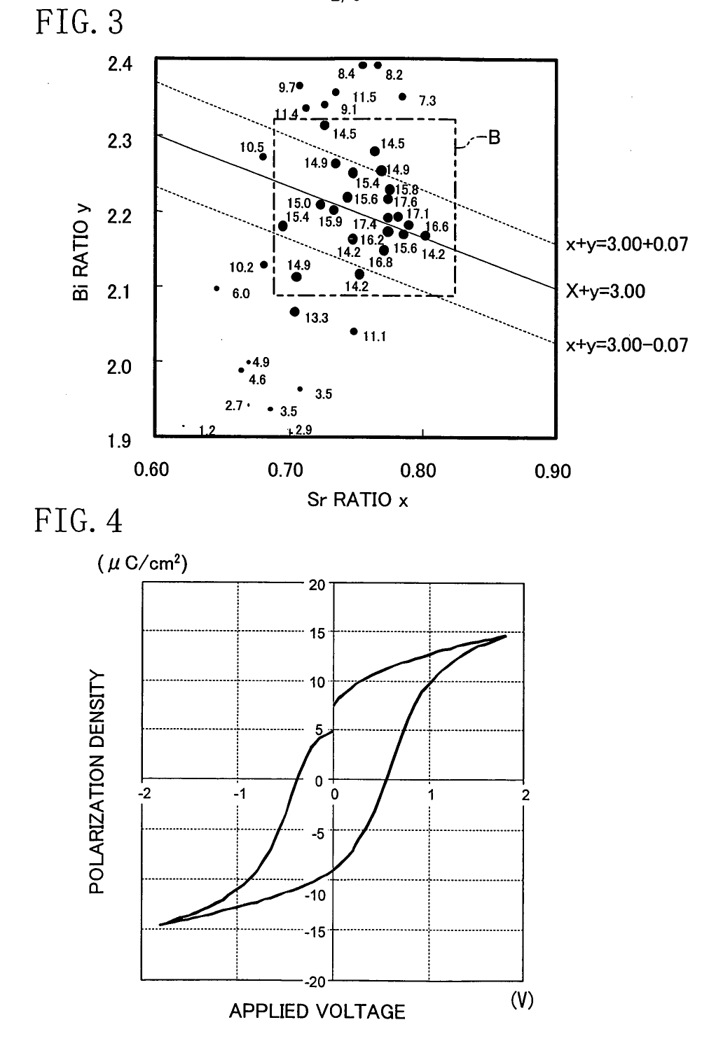

FIG. 3 shows the measurements of remnant polarization density 2Pr of various SBT films different in Sr ratio x and Bi ratio y. A voltage of 1.8 V was applied to the SBT films to measure the 2Pr value. The solid line shown in FIG. 3 is a plot of the compositions where the sum of the Sr ratio x and the Bi ratio y is 3.

The SBT films within the composition region A showed the 2Pr values as low as 6 to 12 μC/cm². In contrast, as shown in FIG. 3, the SBT films within the composition region B of the present embodiment showed high 2Pr values of 14.2 to 17.6 μC/cm² with stability. As an example, FIG. 4 shows a P—V hysteresis curve of an SBT film in which the Sr ratio x is 0.79 and the Bi ratio y is 2.1. The SBT film showed a 2Pr value of 16.6 μC/cm².

As shown in FIG. 3, particularly high 2Pr values are obtained near the lines on which the equation x+y=3.00±0.07 is met in the composition region B. However, in other region than the composition region B, the 2Pr value drops sharply. The reason why the SBT films within the composition region B show higher 2Pr values than those of the SBT films within the other region is provided below.

The 2Pr value depends on the composition and the crystal quality of the SBT film. In general, the SBT film is supposed to be Sr-deficient (x<1) and Bi-excess (y>2) irrespective of the manufacturing method. Specifically, it has been considered that the Bi atoms are positioned at Sr sites in the crystal structure to cause significant displacement of the constituent atoms. The 2Pr value is in proportion to the amount of the atom displacement.

The crystal quality depends on conditions for thermal treatment and the film quality of the SBT film before the thermal treatment. Hereinafter, an SBT film which is not yet subjected to the thermal treatment to obtain a layered perovskite crystal structure is referred to as an SBT precursor. If the SBT precursor is likely to be rearranged to take the layered perovskite crystal structure due to its structure and composition, favorable crystal quality is obtained by the thermal treatment. Even if the SBT precursors are all amorphous from a macroscopic view, they vary in microscopic structure depending on the manufacturing method (including the material selected). Hereinafter, explanation of the microscopic structure of the SBT precursor deposited by MOCVD is provided. During MOCVD, the substrate temperature is supposed to be 400° C. or lower.

It is presumed that the SBT precursor formed by MOCVD and that formed by sputtering at the same substrate temperature (400° C. or lower) have the following differences in structure. According to MOCVD, thermal decomposition and chemical reaction of organic metal material occur on the surface of the substrate to form a film. In sputtering, on the other hand, film deposition is physically performed without causing any chemical reaction of target material on the substrate surface. Therefore, it is considered that the structure of the SBT precursor formed through the chemical reaction by MOCVD becomes more similar to the layered perovskite structure as compared with the structure of the SBT precursor formed by sputtering.

For this reason, the SBT precursor formed by MOCVD is most likely to cause atomic rearrangement to have the layered perovskite structure with favorable crystal quality when its composition is the same as the stoichiometric composition of the layered perovskite crystal. In the stoichiometric composition, x is 1 and y is 2. Therefore, if the sum of x and y is approximately 3, the Bi atoms are positioned at the Sr sites. As a result, the atomic rearrangement is likely to occur. Specifically, in order that the SBT film formed by MOCVD shows high 2Pr, the sum of the Sr ratio x and the Bi ratio y has to be approximately 3.

Nevertheless, the Sr ratio x has to be in an optimum range. As described above, the lower the Sr ratio x is, the more the amount of the displacement of the constituent atoms increases to raise the 2Pr value. However, if the Sr ratio x is too low, the layered perovskite structure cannot be maintained, thereby increasing crystal defects and decreasing the 2Pr value. This is considered as the reason why the 2Pr value sharply drops in the other region than the composition region B as shown in FIG. 3.

Thus, the SBT film formed by MOCVD to have the composition within the composition region B shows a high 2Pr value with stability even if the thickness is reduced to 100 nm or less. This allows the ferroelectric capacitor to perform high speed data writing at low voltage.

In the ferroelectric capacitor of the present embodiment, the electrodes are made of iridium oxide. The 2Pr value improves by using iridium oxide as the electrode material.

For example, if platinum is used as the electrode material in the ferroelectric capacitor provided with the SBT film whose composition is within the composition region A, the 2Pr value is 5 to 10 μC/cm². In contrast, when iridium oxide is used as the electrode material, the 2Pr value is raised to 6 to 12 μC/cm², improved as compared with the ferroelectric capacitor using the platinum electrodes.

Further, also in the ferroelectric capacitor provided with the SBT film whose composition is within the composition region B, the iridium oxide electrodes provide greater improvement in 2Pr value as compared with the platinum electrodes. The 2Pr value is 8 to 10 μC/cm² when the electrodes are made of platinum, while it is 14.2 to 17.6 μC/cm² when the electrodes are made of iridium oxide.

Thus, the reason why the 2Pr value varies depending on the electrode material is as follows. In general, metal oxide such as iridium oxide contains more amorphous components than metal such as iridium or platinum and therefore shows significant lattice mismatch with the SBT layered perovskite crystal structure. Accordingly, when the SBT film is thermally treated for crystallization, it is considered that the lattice mismatch inhibits crystal growth along the c-axis where the remnant polarization density is zero. In the present embodiment, iridium oxide is used as the metal oxide, but it may be replaced with ruthenium oxide or ruthenium strontium oxide.

If the bottom electrode is made of metal oxide and a plug made of tungsten is connected thereto, the plug may possibly be oxidized. In such a case, the bottom electrode may be made of a stack of a metal oxide film and a metal film such that the metal oxide film contacts the SBT film and the metal film such as a platinum film contacts the plug. Or alternatively, an oxygen barrier film may be provided.

### Modification of First Embodiment

Hereinafter, explanation of a modification of the first embodiment is provided below with reference to the drawings. A ferroelectric capacitor according to the modification of the first embodiment is characterized in that tantalum (Ta) in the SBT film is partially substituted with niobium (Nb). Therefore, the ferroelectric material film according to the modification is an SBTN film represented by the general formula of SrₓBi_{y}Ta_{2-z}Nb_{z}O₉ (wherein 0.69≦x≦0.81, 2.09≦y≦2.31 and 0.35≦z≦0.98).

The ferroelectric capacitor according to the modification may be formed by the same method described in the first embodiment except that the SBTN film is formed as the ferroelectric film. The SBTN film is formed by feeding a Nb-containing compound to the substrate surface together with the materials during MOCVD. According to the modification, x and y were fixed to 0.72 and 2.25, respectively, and the feed rates of the materials were adjusted to vary the ratios of Ta and Nb only.

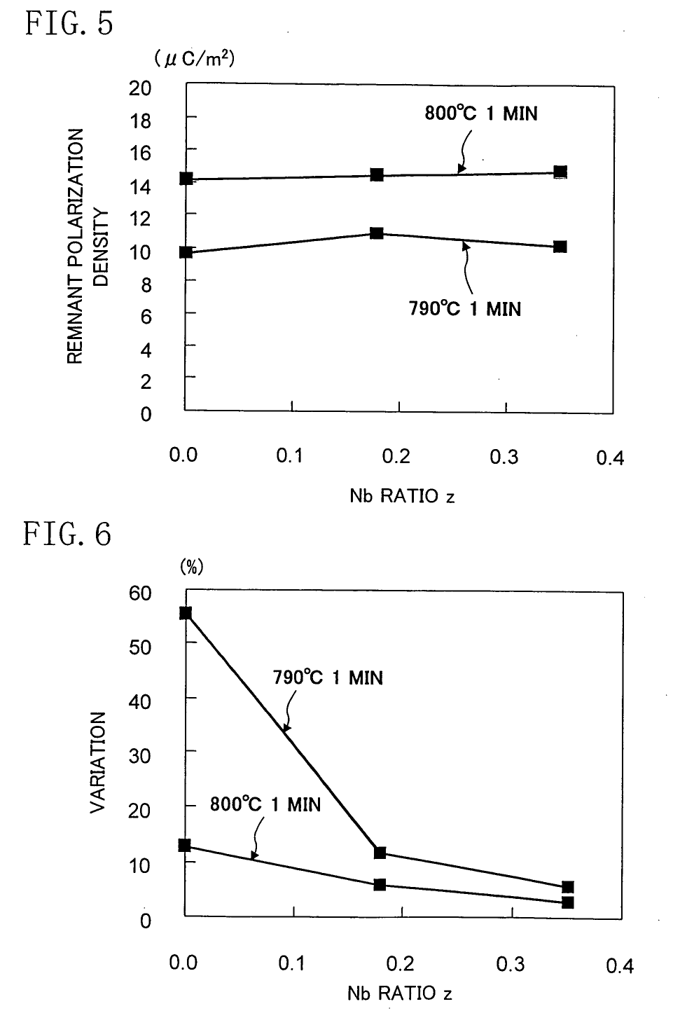

FIG. 5 shows a correlation between 2Pr value and Nb ratio z in the thus obtained ferroelectric capacitor. In FIG. 5, an average taken from the 2Pr values of nine of a plurality of ferroelectric capacitors formed on a 8-inch wafer is plotted. Thermal treatments for crystallizing the ferroelectric material film were performed at 790° C. and 800° C. for comparison.

As shown in FIG. 5, the average 2Pr value is raised higher when the thermal treatment for crystallizing the ferroelectric material film was performed at the higher temperature. It is because the higher thermal treatment temperature improves the crystallinity of the SBTN film. However, the average 2Pr value remains unchanged even if the Nb ratio z is varied irrespective of whether the thermal treatment temperature is 790° C. or 800° C.

FIG. 6 shows a correlation between variation in 2Pr value (σ/Ave) and Nb ratio z. In FIG. 6, the variation is indicated by a value obtained by dividing a standard deviation σ of the 2Pr values of nine of the ferroelectric capacitors formed on the wafer by an average value Ave. Referring to FIG. 6, the variation in the 2Pr values is high when the Nb ratio z is low and the variation further increases as the thermal treatment temperature decreases. However, the variation decreases as the Nb ratio z increases. When the Nb ratio z is 7%, the variation is reduced to 10% or lower irrespective of whether the thermal treatment temperature is 790° C. or 800° C.

The thermal treatment performed at 790° C. for 1 minute results in insufficient crystallization and reduction in 2Pr value, thereby causing significant variation in 2Pr value. However, if the Nb ratio z is set to 0.35 or lower, the variation in 2Pr value caused by the thermal treatment at 790° C. is reduced to the same degree as that through the 1-minute thermal treatment at 800° C. The reduction of the variation in 2Pr value provides an improvement in yield of the ferroelectric capacitors. Further, as the thermal treatment is performed at reduced temperature, the other components formed on the substrate are less damaged.

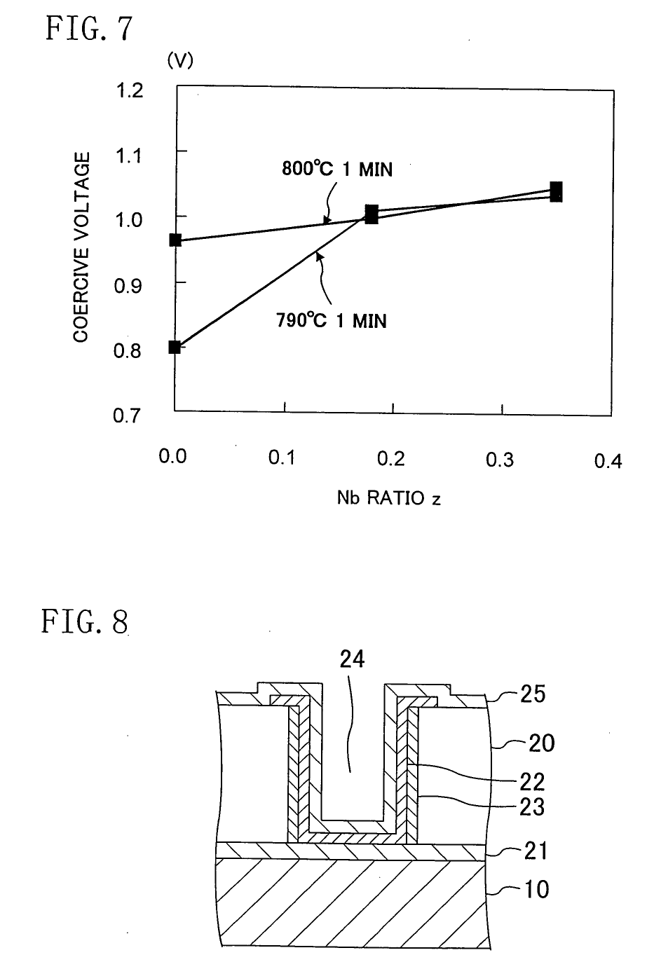

On the other hand, coercive voltage (2Vc) increases as the Nb ratio z increases as shown in FIG. 7. The 2Vc value has to be low in order to perform high speed data writing at low voltage. That is, there is an upper limit to the Nb ratio z. For example, at an applied voltage of 1.8 V, the 2Vc value is preferably 1.2 V or lower in order to perform data writing sufficiently in several hundred nanoseconds. From the 2Vc value obtained when the Nb ratio z is 0.18 and 0.35, the Nb ratio z corresponding to the 2Vc value of 1.2 V is determined as 0.98 by extrapolation. Thus, the Nb ratio z is preferably not lower than 0.35 and not higher than 0.98.

### Second Embodiment

Hereinafter, explanation of a second embodiment of the present invention is provided with reference to the drawings. FIG. 8 shows the sectional structure of a ferroelectric capacitor according to the second embodiment. As shown in FIG. 8, the ferroelectric capacitor of the present embodiment is a concave ferroelectric capacitor having a concave cross section. An interlayer insulating film 20 formed on a substrate 10 has a recess 24. A bottom electrode 21 made of iridium oxide exists at the bottom of the recess 24 and a bottom electrode 23 made of iridium oxide is provided on the sidewalls of the recess 24. The bottom electrodes 21 and 23 are integrated. A ferroelectric material film 22 is formed to cover the bottom electrodes 21 and 23 and part of the top surface of the interlayer insulating film 20 at the periphery of the opening of the recess 24. Further, a top electrode 25 made of iridium oxide is formed on the ferroelectric material film 22.

The ferroelectric capacitor of the present embodiment is manufactured by the following method. First, a 200 nm thick silicon oxide film (not shown) is formed on a silicon substrate 10 by plasma CVD. Then, a bottom electrode 21 made of a 100 nm thick iridium oxide film is formed on the silicon oxide film by sputtering.

Then, a 600 nm thick interlayer insulating film 20 made of silicon oxide is formed on the bottom electrode 21 by plasma CVD. Then, part of the interlayer insulating film 20 and the bottom electrode 21 is etched using a patterned resist as a mask to form a recess 24. In this step, the bottom electrode 21 is etched by about 50 nm such that iridium oxide once deposited as the bottom electrode 21 is re-deposited on the sidewalls of the recess 24, thereby forming a bottom electrode 23 made of iridium oxide on the sidewalls of the recess 24.

Then, the resist is removed and an SBT film 22 is formed by MOCVD. In this step, the feed rates of the materials and deposition time are adjusted such that the thinnest part of the SBT film 22 formed on the sidewalls of the recess 24 is about 60 nm thick, the Sr ratio x is 0.79 and the Bi ratio y is 2.18. According to actually performed SEM observation combined with energy-dispersive X-ray diffraction (EDX), the SBT film formed on the sidewalls of the recess 24 substantially achieved the intended composition.

Then, a top electrode 25 made of a 100 nm thick iridium oxide film is formed on the SBT film 22 by sputtering. After that, thermal treatment is performed in an oxygen atmosphere at 800° C. for 1 minute to crystallize the SBT film 22.

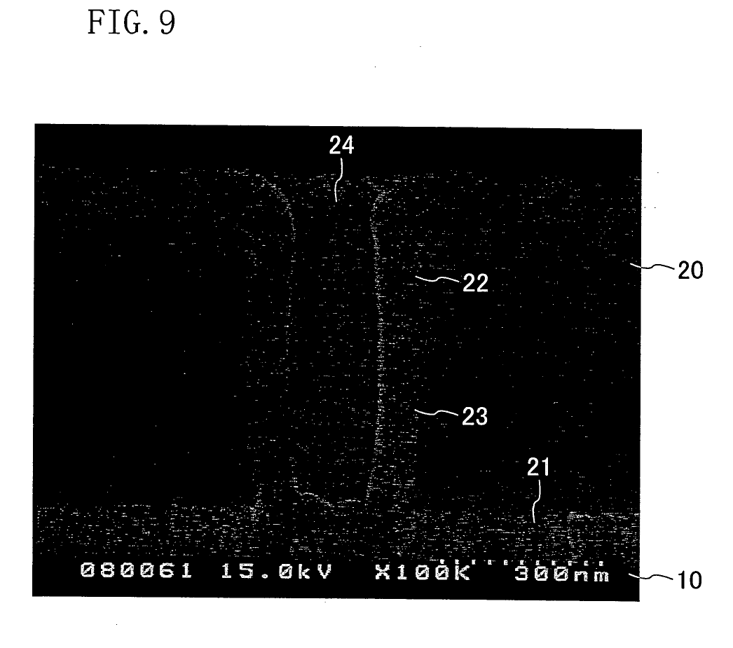

FIG. 9 shows an electron micrograph obtained with a scanning electron microscope (SEM) illustrating the sectional structure of the ferroelectric capacitor of the present embodiment before the formation of the top electrode. From the electron micrograph of FIG. 9, the thickest part and the thinnest part of the SBT film 22 formed on the sidewalls and the bottom surface of the recess 24 are measured. As a result, the thickest part is 73.3 nm and the thinnest part is 66.7 nm. Thus, the thickness ratio obtained by dividing the smallest thickness by the largest thickness is 0.91.

The intensity of an electric field applied to the ferroelectric material film depends on the thickness of the ferroelectric material film. Therefore, if the ferroelectric material film in the ferroelectric capacitor is not uniform in thickness, the intensity of the electric field applied to the ferroelectric material film also varies and high speed data writing may possibly fail. Therefore, the thickness ratio of the ferroelectric material film has to be 0.8 or higher. It is substantially impossible to form a ferroelectric material film having such a high thickness ratio by conventional sputtering. However, since the ferroelectric material film in the ferroelectric capacitor of the present embodiment is formed by MOCVD, the thickness ratio of the SBT film is significantly raised. As a result, no significant difference occurs between the intensity of the electric field applied to the thickest part of the SBT film and that applied to the thinnest part, thereby allowing high speed data writing. Further, since even the thickest part of the SBT film is as thin as 73 nm, high speed data wiring is performed at a voltage as low as 2 V or lower.

The SBT film used in the concave ferroelectric capacitor of the present embodiment shows a 2Pr value as high as 16.6 μC/cm² even if the thickness is 100 nm or less. Therefore, the concave ferroelectric capacitor can be designed under finer rules.

The ferroelectric capacitor of the present embodiment may also include an SBTN film in the same manner as described in the modification of the first embodiment.

### Modification of Second Embodiment

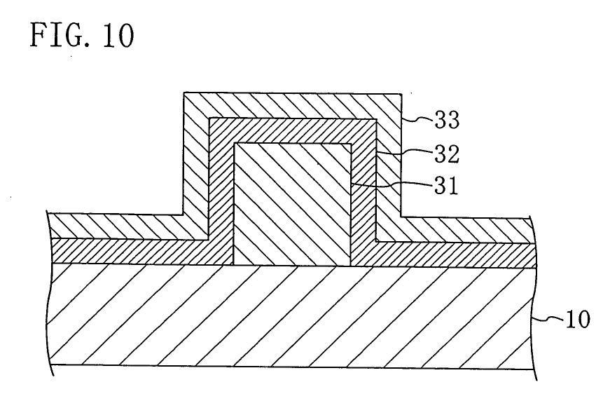

Hereinafter, explanation of a modification of the second embodiment is provided with reference to the drawings. FIG. 10 shows the sectional structure of a ferroelectric capacitor according to the modification of the second embodiment.

As shown in FIG. 10, the ferroelectric capacitor according to the modification includes a bottom electrode 31 formed on a silicon substrate 10 to be projected from the substrate surface, an SBT film 32 formed on the sidewalls and the top surface of the bottom electrode 31 and a top electrode 33 covering the SBT film 32. Even in this convex ferroelectric capacitor, the SBT film is formed on the sidewalls and the top surface of the projected bottom electrode with reduced thickness and less variation in thickness. Thus, the ferroelectric capacitor makes it possible to perform high speed data writing at low voltage.

In the above-described embodiments and modifications, the ferroelectric material film may contain a slight amount of rare earth element. The addition of the rare earth element improves the 2Pr value to a further extent. For example, as a preferable rare earth element, praseodymium may be added in an amount less than 1%.

Though not described in the above-described embodiments and modifications, MOS transistors formed on the substrate, interlayer insulating films formed between the substrate and the ferroelectric capacitors and contact plugs for connecting the MOS transistors and the ferroelectric capacitors may be provided.

Thus, the ferroelectric capacitor of the present invention is effective in that it includes a strontium bismuth tantalum oxide film having a high remnant polarization density even with a thickness of 100 nm or less. Therefore, the ferroelectric capacitor of the present invention is useful for a ferroelectric memory.

What is claimed is:

1. A ferroelectric capacitor comprising:
a bottom electrode formed on a substrate;
a ferroelectric material film formed on the bottom electrode and predominantly made of a compound represented by the general formula of SrₓBi_{y}Ta_{2-z}Nb_{z}O₉ (wherein 0.69≦x≦0.81, 2.09≦y≦2.31 and z=0 or 0.35≦z≦0.98); and
a top electrode formed on the ferroelectric material film.

2. The ferroelectric capacitor of claim 1, wherein
the bottom electrode is formed on the substrate with a first interlayer insulating film interposed therebetween.

3. The ferroelectric capacitor of claim 1, wherein
the sum of the Sr ratio and the Bi ratio is 3.00±0.07.

4. The ferroelectric capacitor of claim 1, wherein
the thickness of the ferroelectric material film is larger than 0 nm and not larger than 100 nm.

5. The ferroelectric capacitor of claim 1, wherein
the ferroelectric material film is formed by metal-organic chemical vapor deposition.

6. The ferroelectric capacitor of claim 1 wherein,
a second interlayer insulating film having a recess is formed on the substrate,
the ferroelectric material film is formed along the shape of the recess and
the ratio between the maximum thickness and the minimum thickness of the ferroelectric material film formed along the shape of the recess is 0.8 or higher.

7. The ferroelectric capacitor of claim 6, wherein
the second interlayer insulating film is formed on the substrate with the first interlayer insulating film interposed therebetween.

8. The ferroelectric capacitor of claim 1, wherein
the bottom electrode is formed to be projected from the surface of the substrate,
the ferroelectric material film is formed along the shape of the bottom electrode and
the ratio between the maximum thickness and the minimum thickness of the ferroelectric material film formed along the shape of the bottom electrode is 0.8 or higher.

9. The ferroelectric capacitor of claim 8, wherein
the bottom electrode is formed on the substrate with the first interlayer insulating film interposed therebetween.

10. The ferroelectric capacitor of claim 1, wherein
the bottom electrode is made of a single metal oxide film or a stack of films including a metal oxide film arranged nearest the ferroelectric material film.

11. The ferroelectric capacitor of claim 1, wherein
the ferroelectric material film contains a rare earth element.
